(19) United States
(12) Patent Application Publication
(10) Pub. No.: US 2025/0311275 A1
(43) Pub. Date: Oct. 2, 2025

(54) STRAINED OHMIC CONTACT HIGH ELECTRON MOBILITY TRANSISTOR

(71) Applicant: International Business Machines Corporation, Armonk, NY (US)

(72) Inventors: Bogdan Cezar Zota, Rueschlikon (CH); Eunjung Cha, Adliswill (CH)

(21) Appl. No.: 18/616,555

(22) Filed: Mar. 26, 2024

(51) Int. Cl. H01L 29/778; H01L 29/423; H01L 29/66

(52) U.S. Cl. CPC H10D 30/4732; H10D 30/015; H10D 64/512

(57) ABSTRACT

One or more systems, devices and/or methods of fabrication provided herein relate to forming a strained ohmic contact on a high electron mobility transistor (HEMT) semiconductor device. According to one embodiment, a plurality of semiconductor layers that comprises a barrier layer on top of a quantum well layer is formed and, a T-gate is placed above a plurality of semiconductor layers and between a first doped contact layer and a second doped contact layer. According to another embodiment, a tensile strained (TS) contact layer is deposited on the first and the second doped contact layer, wherein the TS contact layer is a stiff metal deposited with tensile internal stress, and wherein a linear expansion coefficient as a function of temperature of the stiff metal is larger than the linear expansion coefficient of the plurality of semiconductor layers, to induce a reduction of tunneling resistance through the barrier layer.

### BACKGROUND

The subject disclosure relates to semiconductors and, more specifically, to forming a strained ohmic contact high electron mobility transistors (HEMT).

Semiconductor devices, particularly HEMTs, are used in components of many electronic devices. More specifically, HEMTs are key components in developing Low-Noise Amplifiers (LNAs). HEMTs provide high-frequency performance and low noise characteristics in applications of cryogenic LNAs. However, HEMTs used in cryogenic LNAs can experience degraded noise performance due to increased thermal noise from parasitic resistances. Additionally, HEMTs used in cryogenic LNAs can experience increased power consumption due to the biasing currents needed to maintain device operation and performance at low temperatures. Thus, systems and/or methods that can address this technical problem, and improve HEMT performance, are needed.

The above-described background description is merely intended to provide a contextual overview regarding semiconductor devices and is not intended to be exhaustive.

### SUMMARY

The following presents a summary to provide a basic understanding of one or more embodiments described herein. This summary is not intended to identify key or critical elements, delineate scope of particular embodiments or scope of claims. Its sole purpose is to present concepts in a simplified form as a prelude to the more detailed description that is presented later. In one or more embodiments described herein, systems, computer-implemented methods, apparatus and/or computer program products that enable forming a strained ohmic contact in a semiconductor device are discussed.

According to an embodiment, a semiconductor device is provided. The semiconductor device can comprise a plurality of semiconductor layers that comprises a barrier layer on top of a quantum well layer. The semiconductor device can further comprise a T-gate above the plurality of semiconductor layers and between a first contact layer and a second contact layer. The semiconductor device can further comprise a tensile strained (TS) contact layer on the first and the second contact layer, wherein the TS contact layer is a stiff metal deposited with tensile internal stress to induce a reduction of tunneling resistance through the barrier layer. This can occur through the internal stress of the TS contact layer, engineered by the material choice, thickness and deposition conditions; or by the thermal expansion of the TS contact layer at cryogenic temperatures. The effect of the straining is to induce an increased electron density at the barrier layer. Such embodiment of the semiconductor device can provide a number of advantages, including that the TS contact layer reduces the barrier tunneling resistance in the semiconductor device at cryogenic temperatures, and thus decreases noise and power of the semiconductor device.

According to another embodiment, a method for fabricating a semiconductor device is provided. The method can comprise forming a plurality of semiconductor layers that comprises a barrier layer on top of a quantum well layer. The method can further comprise placing a T-gate above the plurality of semiconductor layers and between a first contact layer and a second contact layer. The method can further comprise depositing a tensile strained (TS) contact layer on the first and the second contact layer, wherein the TS contact layer is a stiff metal deposited with tensile internal stress to induce a reduction of tunneling resistance through the barrier layer. Such embodiment of the method can provide a number of advantages, including that the TS contact layer induces electron density at the barrier layer to reduce the barrier tunneling resistance in the semiconductor device at cryogenic temperatures, and thus decrease noise and power of the semiconductor device.

According to another embodiment, a semiconductor device is provided. The semiconductor device can comprise a plurality of semiconductor layers that comprises an indium aluminum arsenide (InAlAs) barrier layer on top of an InGaAs quantum well. The semiconductor device can further comprise a T-gate above the plurality of semiconductor layers and between a first indium gallium arsenide (InGaAs) contact layer and a second InGaAs contact layer. The semiconductor device can further comprise a tensile strained (TS) contact layer on the first and the second InGaAs contact layer, wherein the TS contact layer is a stiff metal deposited with tensile internal stress to induce a reduction of tunneling resistance through the InAlAs barrier layer. Such embodiment of the semiconductor device can provide a number of advantages, including that the TS contact layer induces electron density at the InAlAs barrier layer to reduce the tunneling barrier resistance in the semiconductor device at cryogenic temperatures, and thus decrease noise and power of the semiconductor device.

### BRIEF DESCRIPTION OF THE DRAWINGS

FIG. 1 illustrates an example, non-limiting cross-sectional view of a strained ohmic contact semiconductor device in accordance with one or more embodiments described herein.

FIG. 2 illustrates an example, non-limiting low noise amplifier, monolithic microwave integrated circuit, and a semiconductor device in accordance with one or more embodiments described herein.

FIG. 3 illustrates an example, non-limiting cross-sectional view of parasitic resistances in a semiconductor device, in accordance with one or more embodiments described herein.

FIG. 4 illustrates an example, non-limiting cross-sectional view of a strained ohmic contact semiconductor device in accordance with one or more embodiments described herein.

FIGS. 5A-5E illustrates example, non-limiting cross-sectional views of steps in a semiconductor device fabrication process in accordance with one or more embodiments described herein.

FIG. 6 illustrates an example, non-limiting graph of electron density in a strained ohmic contact semiconductor device in accordance with one or more embodiments described herein.

FIG. 7 illustrates an example, non-limiting graph of noise levels in a strained ohmic contact semiconductor device in accordance with one or more embodiments described herein.

FIG. 8 illustrates an example, non-limiting graph of noise levels in a strained ohmic contact semiconductor device in accordance with one or more embodiments described herein.

FIG. 9 illustrates an example, non-limiting graph of on-state resistance in a strained ohmic contact semiconductor device in accordance with one or more embodiments described herein.

FIG. 10 illustrates an example, non-limiting graph of barrier resistance in a strained ohmic contact semiconductor device in accordance with one or more embodiments described herein.

FIG. 11 illustrates an example, non-limiting graph of barrier resistance and source-drain resistance in a strained ohmic contact semiconductor device in accordance with one or more embodiments described herein.

FIG. 12 illustrates a flow diagram of an example, non-limiting method in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

According to an embodiment, a semiconductor device is provided. The semiconductor device can comprise a plurality of semiconductor layers that comprises a barrier layer on top of a quantum well layer. The semiconductor device can further comprise a T-gate above the plurality of semiconductor layers and between a first contact layer and a second contact layer. The semiconductor device can further comprise a tensile strained (TS) contact layer on the first and the second contact layer, wherein the TS contact layer is a stiff metal deposited with tensile internal stress to induce a reduction of tunneling resistance through the barrier layer. This can occur through the internal stress of the TS contact layer, engineered by the material choice, thickness and deposition conditions; or by the thermal expansion of the TS contact layer at cryogenic temperatures. The effect of the straining is to induce an increased electron density at the barrier layer. Such embodiment of the semiconductor device can provide a number of advantages, including that the TS contact layer reduces the barrier tunneling resistance in the semiconductor device at cryogenic temperatures, and thus decreases noise and power of the semiconductor device.

In one or more embodiments of the semiconductor device, a linear expansion coefficient as a function of temperature of the stiff metal is larger than the linear expansion coefficient as a function of temperature of the plurality of semiconductor layers. In one or more embodiments of the semiconductor device, the TS contact layer can comprise a thickness between 60 nm to 200 nm. In one or more embodiments of the semiconductor device, thickness of the TS contact layer can be set to adjust strain on the first and the second contact layer. In one or more embodiments of the semiconductor device, the contact TS layer can comprise sputtered niobium (Nb), tungsten (W), or molybdenum (Mo) deposited under conditions of tensile stress above 100 MPa. In one or more embodiments of the semiconductor device, strain on the first and the second contact layer via the TS contact layer can compressively stress the plurality of semiconductor layers by at least 100 MPa when cooled to temperatures below 77 K. In one or more embodiments of the semiconductor device, the TS contact layer can comprise a plurality of stiff metal layers with a combined internal tensile stress of above 100 MPa, and wherein the plurality of stiff metal layers comprises a Young's modulus above 100 GPa. The semiconductor device can further comprise a source region on the TS contact layer on the first contact layer, and a drain region on the TS contact layer on the second contact layer. In one or more embodiments of the semiconductor device, the plurality of semiconductor layers can further comprise a substrate located at a bottom of the plurality of semiconductor layers, and a buffer layer above the substrate to connect the substrate to other layers of the plurality of semiconductor layers. Such embodiment of the semiconductor device can provide a number of advantages, including providing more strain at room temperature to induce electron carrier density, allowing strain to be adjusted, or increased tunneling rate through the barrier layer.

According to another embodiment, a method for fabricating a semiconductor device is provided. The method can comprise forming a plurality of semiconductor layers that comprises a barrier layer on top of a quantum well layer. The method can further comprise placing a T-gate above the plurality of semiconductor layers and between a first contact layer and a second contact layer. The method can further comprise depositing a tensile strained (TS) contact layer on the first and the second contact layer, wherein the TS contact layer is a stiff metal deposited with tensile internal stress to induce a reduction of tunneling resistance through the barrier layer. Such embodiment of the method can provide a number of advantages, including that the TS contact layer induces electron density at the barrier layer to reduce the barrier tunneling resistance in the semiconductor device at cryogenic temperatures, and thus decrease noise and power of the semiconductor device.

In one or more embodiments of the method, a linear expansion coefficient as a function of temperature of the stiff metal is larger than the linear expansion coefficient as a function of temperature of the plurality of semiconductor layers. In one or more embodiments of the method, the TS contact layer can comprise a thickness between 60 nm to 200 nm. In one or more embodiments of the method, thickness of the TS contact layer can be set to adjust strain on the first and the second contact layer. In one or more embodiments of the method, the contact TS layer can comprise sputtered niobium (Nb), tungsten (W), or molybdenum (Mo) deposited under conditions of tensile stress above 100 MPa. In one or more embodiments of the method, strain on the first and the second contact layer via the TS contact layer can compressively stress the plurality of semiconductor layers by at least 100 MPa when cooled to temperatures below 77 K. In one or more embodiments of the method, the TS contact layer can comprise a plurality of stiff metal layers with a combined internal tensile stress above 100 MPa, and wherein the plurality of stiff metal layers comprises a Young's modulus above 100 GPa. The aforementioned method can further comprise depositing a source region on the TS contact layer on the first contact layer, and depositing a drain region on the TS contact layer on the second contact layer. In one or more embodiments of the method, the plurality of semiconductor layers can further comprise a substrate located at a bottom of the plurality of semiconductor layers, and a buffer layer above the substrate to connect the substrate to other layers of the plurality of semiconductor layers. Such embodiment of the method can provide a number of advantages, including providing more strain at room temperature to induce electron carrier density, allowing strain to be adjusted, or increased tunneling rate through the barrier layer.

According to another embodiment, a semiconductor device is provided. The semiconductor device can comprise a plurality of semiconductor layers that comprises an indium aluminum arsenide (InAlAs) barrier layer on top of an InGaAs quantum well. The semiconductor device can further comprise a T-gate above the plurality of semiconductor layers and between a first indium gallium arsenide (InGaAs) contact layer and a second InGaAs contact layer. The semiconductor device can further comprise a tensile strained (TS) contact layer on the first and the second InGaAs contact layer, wherein the TS contact layer is a stiff metal deposited with tensile internal stress to induce a reduction of tunneling resistance through the InAlAs barrier layer. Such embodiment of the semiconductor device can provide a number of advantages, including that the TS contact layer induces electron density at the InAlAs barrier layer to reduce the tunneling barrier resistance in the semiconductor device at cryogenic temperatures, and thus decrease noise and power of the semiconductor device

In one or more embodiments of the semiconductor device, a linear expansion coefficient as a function of temperature of the stiff metal is larger than the linear expansion coefficient as a function of temperature of the plurality of semiconductor layers. In one or more embodiments of the semiconductor device, the plurality of semiconductor layers can comprise an InGaAs channel layer that is connected to one or more quantum wells via the first and the second InGaAs contact layer. In one or more embodiments of the semiconductor device, the contact TS layer can comprise sputtered niobium (Nb), tungsten (W), or molybdenum (Mo) deposited under conditions of tensile stress above 100 MPa. Such embodiment of the method can provide a number of advantages, including providing more strain at room temperature to induce electron carrier density, allowing strain to be adjusted, or increased tunneling rate through the barrier layer.

Semiconductors, particularly High Electron Mobility Transistors (HEMTs), are used in components of several electronic devices, such as Low-Noise Amplifiers (LNAs). More specifically, HEMTs are key components in developing cryogenic LNAs for applications such as radio astronomy, quantum computing, satellite space communication, or particle physics. Parasitic resistances in semiconductor devices can cause increased thermal noise and ohmic heating, resulting in increased power or noise in the semiconductor device. Accordingly, cryogenic LNAs can experience increased power consumption due to biasing currents to maintain device operation and performance at low temperatures. The barrier layer of a semiconductor device can provide significant amounts of resistance to current through the semiconductor device based on materials and interfaces within the semiconductor device. Barrier resistance refers to the resistance encountered by electrons as the electrons tunnel through the barrier layer and can account for a substantial portion of total resistance in the semiconductor device. Conventional methods of fabricating a semiconductor device do not adequately address the problem of degraded noise performance and increased power consumption of HEMTs, or solutions for these problems. Thus, methods and structures that can address one or more of the challenges discussed herein while being easy to detect, use and implement in the industry, can be desirable.

To that end, various embodiments herein relate to a unique structure and method of forming a semiconductor device that can have a number of advantages. For example, the various embodiments herein can comprise a semiconductor device that can be fabricated to comprise a TS contact layer below a source contact and a drain contact of the semiconductor device. The TS contact layer can be formed such that the TS contact layer strains a doped contact layer beneath each TS contact layer of the semiconductor device, thereby inducing electron carrier density at a barrier layer, and reducing barrier resistance. The various embodiments of the semiconductor device discussed herein can be applicable to electronic devices, such as high performance or low power logic devices, memories, etc.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively form a TS contact layer below a source contact layer and a drain contact layer of a semiconductor device as the one or more embodiments described herein can enable this process. And, neither can the human mind nor a human with pen and paper form a TS contact layer below a source contact layer and a drain contact layer of a semiconductor device, as conducted by one or more embodiments described herein.

It should also be understood that when an element such as a Niobium layer, etc. is referred to as being “on” or “over” another element, it can be directly on the other element or intervening elements can also be present. In contrast, when an element is referred to as being “directly on” or “directly over” another element, there are no intervening elements present. It should also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

These and other aspects and embodiments of the disclosed subject matter will now be described with respect to the drawings. It is to be appreciated that the words “semiconductor”, “semiconductor device” and “semiconductor chip” have been used interchangeably throughout this specification.

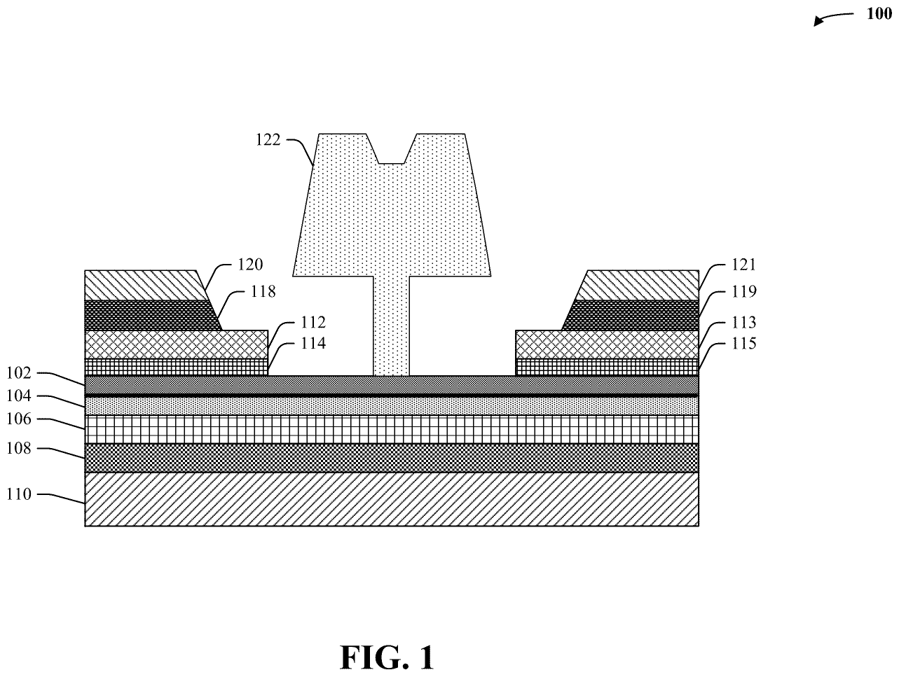

FIG. 1 illustrates an example, non-limiting cross-sectional view 100 of a strained ohmic contact semiconductor device in accordance with one or more embodiments described herein.

In an embodiment, a semiconductor device can comprise a plurality of semiconductor layers, a T-gate, a first and a second doped contact layer, and TS contact layer. In an embodiment, the plurality of semiconductor layers can comprise a substrate 110, a buffer 108 above the substrate 110, a channel 106 above the buffer 108, a spacer 104 above the channel 106, and a barrier layer 102 above the spacer 104. In FIG. 1, the first and the second doped contact layer is illustrated as doped contact layer 112 and doped contact layer 113. In embodiments described herein, the doped contact layer 112 and doped contact layer 113 comprise n-type doping (e.g., element from Group V, such as Phosphorous or arsenic, are added to create an excess of electrons). Further, in FIG. 1, the T-gate is illustrated as T-gate 122, wherein T-gate 122 is located above the plurality of semiconductor layers and between doped contact layer 112 and doped contact layer 113. Moreover, as illustrated in FIG. 1, the TS contact layers are identified by TS contact layer 118 and TS contact layer 118, wherein TS contact layer 119 is located above doped contact layer 112 and TS contact layer 119 is located above doped contact layer 113. In an embodiment, the semiconductor device can further comprise etch stops a source region, and a drain region. In FIG. 1, the etch stops are illustrated as etch stop 114 and etch stop 115, wherein etch stop 114 is located below doped contact layer 112 and etch stop 115 located below doped contact layer 113. The source region can comprise a source contact 120 above TS contact layer 118 and a drain contact 121 above TS contact layer 119.

It is to be appreciated that several layers and features of the semiconductor device illustrated in the cross-sectional views of FIG. 1 are also illustrated in cross-sectional views shown in other figures, although only some layers are discussed in detail for sake of brevity.

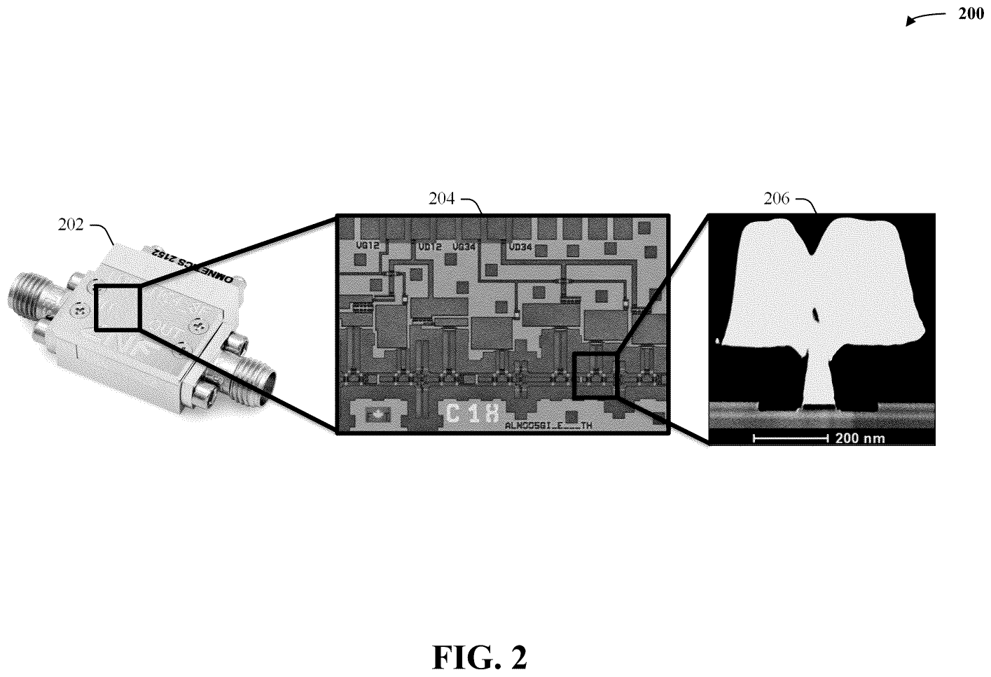

FIG. 2 illustrates an example, non-limiting low noise amplifier, monolithic microwave integrated circuit, and a semiconductor device in accordance with one or more embodiments described herein.

The semiconductor device as described in the herein embodiments can be a component of an LNA 202. LNAs, specifically cryogenic LNAs are amplifiers designed to operate at extremely low temperatures, typically around 4 Kelvin (K), with the purpose of amplifying weak signals with minimal added noise in applications such as quantum computing. More specifically, cryogenic LNAs are key components in control and readout electronics of quantum computers by providing gain to bring qubit signals out of a cryostat. Cryogenic LNAs can comprise a monolithic microwave integrated circuit (MMIC) 204. MMICs are integrated circuits comprising active components and passive components, such as amplifiers, oscillators, or mixers, on a single semiconductor chip for high-frequency applications. The active components of an MMIC can comprise an HEMT 206 (or more than one HEMT). The methods, systems and/or devices described herein can be implemented to fabricate HEMT 206 for utilization in MMICs and LNAs to provide a number of advantages, including reduced power or reduced noise in the semiconductor device or HEMT, which can enable a cryostat to comprise a larger number of qubits.

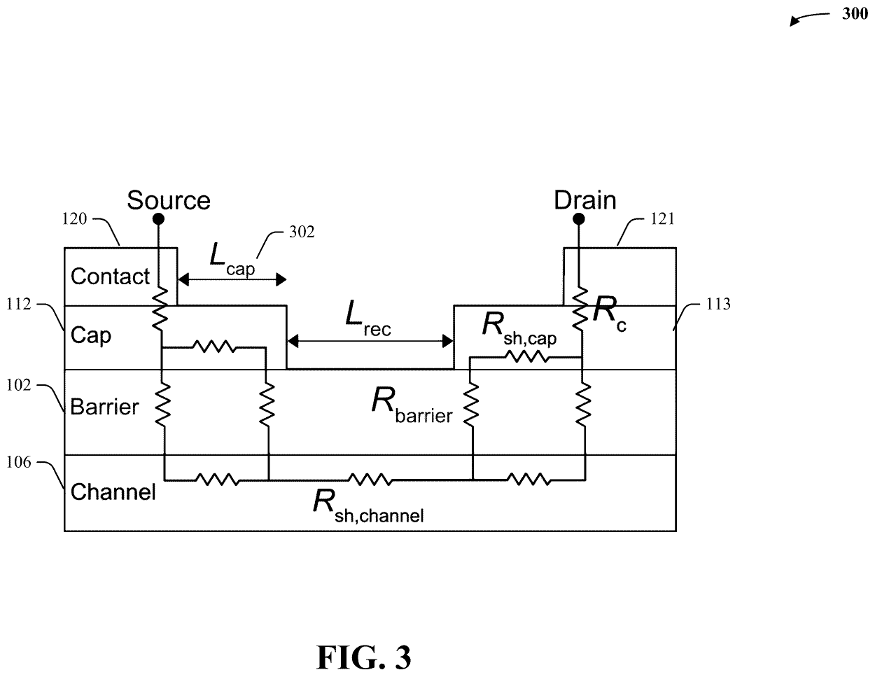

FIG. 3 illustrates an example, non-limiting cross-sectional view 300 of current and parasitic resistances in a semiconductor device, in accordance with one or more embodiments described herein.

Performance of the semiconductor device can be characterized by parameters including noise (e.g., added effective noise temperature at output), added gain (e.g., gain of the amplifier), and power (e.g., power that the LNA is dissipating). Noise temperature can be modeled by the following equation:

$${T}_{m i n} \approx 2 \frac{f}{{f}_{T}} \sqrt{{R}_{G} {T}_{g} {T}_{d} {G}_{d}} , where {T}_{m i n} ∝ \frac{\sqrt{{I}_{DS}}}{{g}_{m}}$$

Tₘᵢₙ denotes minimum noise temperature, f denotes frequency, f_{T} denotes transistor's (e.g., the semiconductor device, HEMT) cut-off frequency (e.g., highest frequency at which the transistor is giving gain), R_{G} denotes gate resistance, T_{g} denotes gate temperature, T_{d} denotes drain temperature, G_{d} denotes transconductance of the transistor, I_{DS} denotes drain current, and gₘ denotes transconductance gain of the semiconductor device.

It can be desired to minimize the parasitic resistances in the semiconductor device to produce low-noise and low-power LNAs that can minimize noise temperature. More specifically, it can be desired to minimize the following parasitic resistances:

$${R}_{source} = {R}_{c} + {R}_{cap} + {R}_{barrier} + {R}_{channel}$$

R_{source} denotes total source resistance, R_{c} denotes contact resistance, R_{cap} denotes resistance related to capacitance effects, R_{barrier} denotes barrier resistance, and R_{channel} denotes channel resistance, where R_{barrier} typically accounts for about 60% of R_{source}. Therefore, it can be desirable to reduce barrier resistance, R_{barrier}, to decrease noise and power of the semiconductor device by increasing transconductance gain, gₘ, to minimize

$$\frac{\sqrt{{I}_{DS}}}{{g}_{m}}$$

(which is directly proportional to minimum noise temperature Tₘᵢₙ). The methods, systems and/or devices described herein can reduce such barrier resistance in a semiconductor device by inducing electron carrier density at the barrier layer 102.

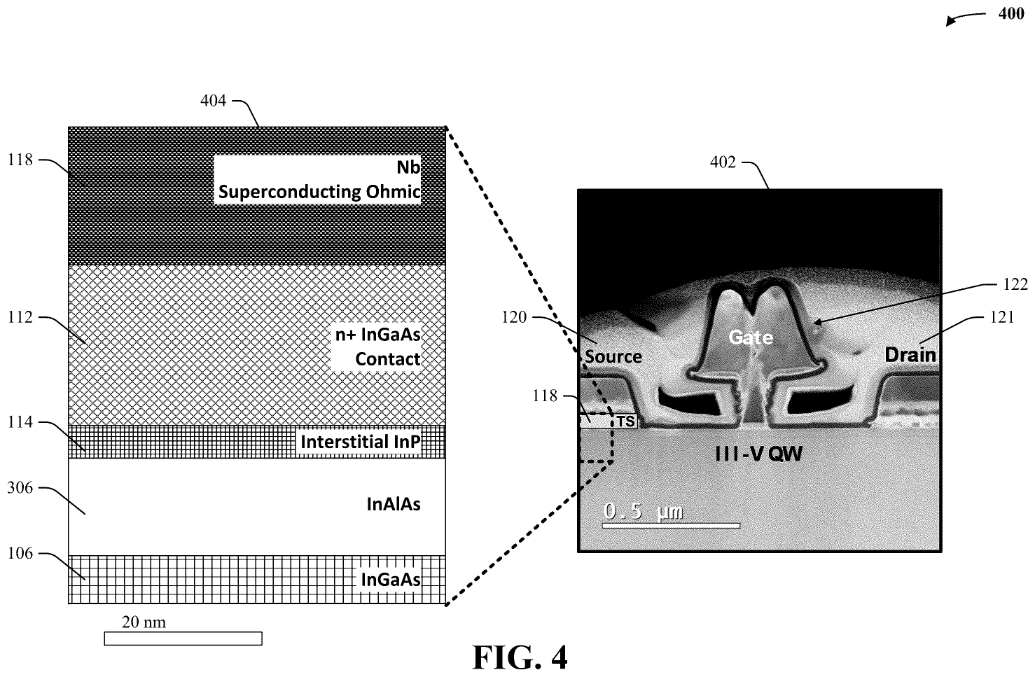

FIG. 4 illustrates an example, non-limiting cross-sectional view 400 of a fabricated strained ohmic contact semiconductor device in accordance with one or more embodiments described herein. Repetitive description of like elements and/or processes employed in respective embodiments is omitted for sake of brevity.

In FIG. 4, a fabricated semiconductor device 402 can comprise source contact 120, drain contact 121, T-gate 122, and TS contact layer 118. As illustrated by magnified view 404, the fabricated semiconductor device 402 can further comprise the plurality of semiconductor layers, particularly doped contact layer 112, etch stop 114, barrier layer 102, spacer 104, and channel 106, where barrier layer 102 and spacer 104 are identified by 406.

In an embodiment, the TS contact layer 118 and the TS contact layer 119 can be composed of a superconducting ohmic metal. In some embodiments, the TS contact layer 118 and the TS contact layer 119 can be formed from Niobium (Nb). However, the TS contact layer 118 and the TS contact layer 119 can be formed from any suitable material or elements (e.g., tungsten (W), molybdenum (Mo)). In particular, any suitable material or elements comprising a suitable thermal expansion coefficient, and high stiffness (Young's modulus>100 GPa) can be used to form the TS contact layer 118 and the TS contact layer 119. In any case, the TS contact layer 118 and the TS contact layer 119 can be deposited under conditions of tensile stress above 100 MPa. In some embodiments, the TS contact layer 118 and the TS contact layer 119 can comprise a plurality of stiff metal layers with a combined internal tensile stress of above 100 MPa.

Utilizing Nb to form the TS contact layer 118 and the TS contact layer 119 provides the advantage of causing more stress at room temperatures due to deposition conditions of Nb. More specifically, Nb has a thermal expansion coefficient of 7.3 μm/(m·K), indicating that it has large amounts of strain at room temperature, as well as while cooling down. Due to difference between the thermal expansion coefficient of Nb and the plurality of semiconductor layers, the TS contact layer 118 and the TS contact layer 119 can expand more than the plurality of semiconductor layers, thereby creating tensile strain in the TS contact layers. In the fabricated semiconductor device 402, the Nb is sputtered with 250 MPa tensile strain at room temperature. Deposition conditions can be altered to adjust thickness of the TS contact layer 118 and the TS contact layer 119. More specifically, thicker TS contact layers provide more strain and can range in thickness between 60 nm to 200 nm.

In some embodiments, doped contact layer 112 and doped contact layer 113 can be formed from n⁺ Indium Gallium Arsenide (InGaAs). However, the doped contact layer 112 and the doped contact layer 113 can be formed from any suitable material or elements (e.g., n⁺ Gallium Arsenide (GaAs), p⁺ GaAs, n⁺ Silicon (Si), n⁺ Indium Phosphide (InP), p⁺ Si). In some embodiments, the etch stop 114 and the etch stop 115 can be formed from interstitial InP. In some other embodiments, the etch stop 114 and the etch stop 115 can be formed from any suitable material or elements (e.g., Aluminum Oxide (Al₂O₃), Silicon Dioxide (SiO₂), Silicon Nitride (Si₃N₄), photoresist materials). In other embodiments, the barrier layer 102 and the spacer 104 can be formed from Indium Aluminum Arsenide (InAlAs). However, the barrier layer 102 can be formed from any suitable material or elements (e.g., Aluminum Gallium Nitride (AlGaN), Aluminum Gallium Arsenide (AlGaAs), InP, Gallium Phosphide (GaP), Si₃N₄). Further, the spacer 104 can be formed from any suitable material or elements (e.g., AlGaAs, Si₃N₄, SiO₂), In an embodiment the channel 106 can be formed from InGaAs. In other embodiments, the channel 106 can be formed from any suitable material or elements (e.g., GaAs, Gallium Nitride (GaN), AlGaN, Si). In some embodiments, the substrate 110 can be semiconductor InP. However, the substrate 110 can be formed from any suitable material or elements (e.g., Al₂O₃, Si, GaN, Silicon Carbide (SiC), GaP, Silicon Germanium (SiGe), GaAs). In some other embodiments, any suitable materials can be used to form such layers of the plurality of semiconductor layers.

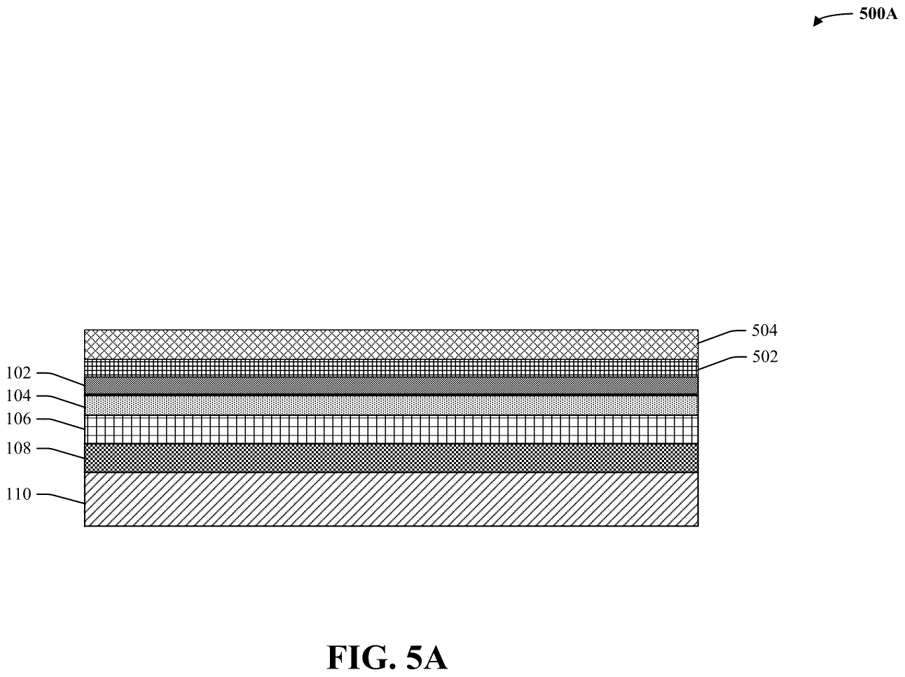

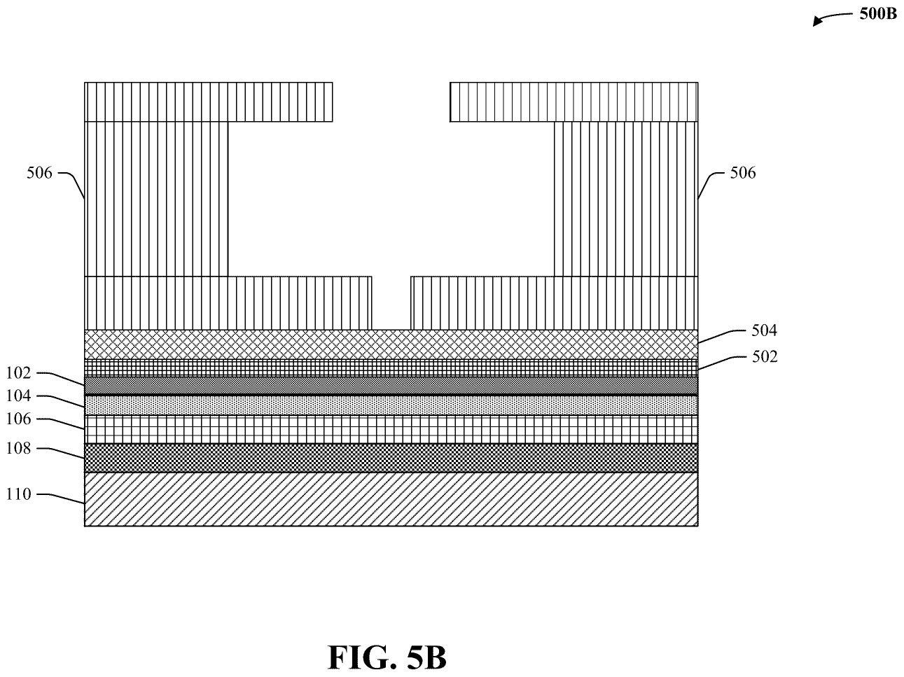

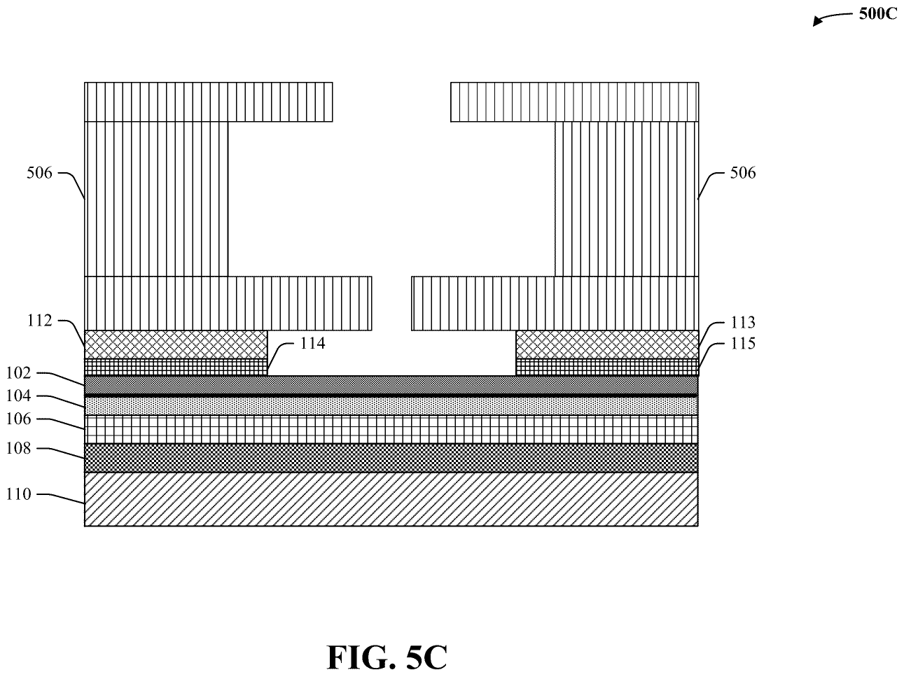

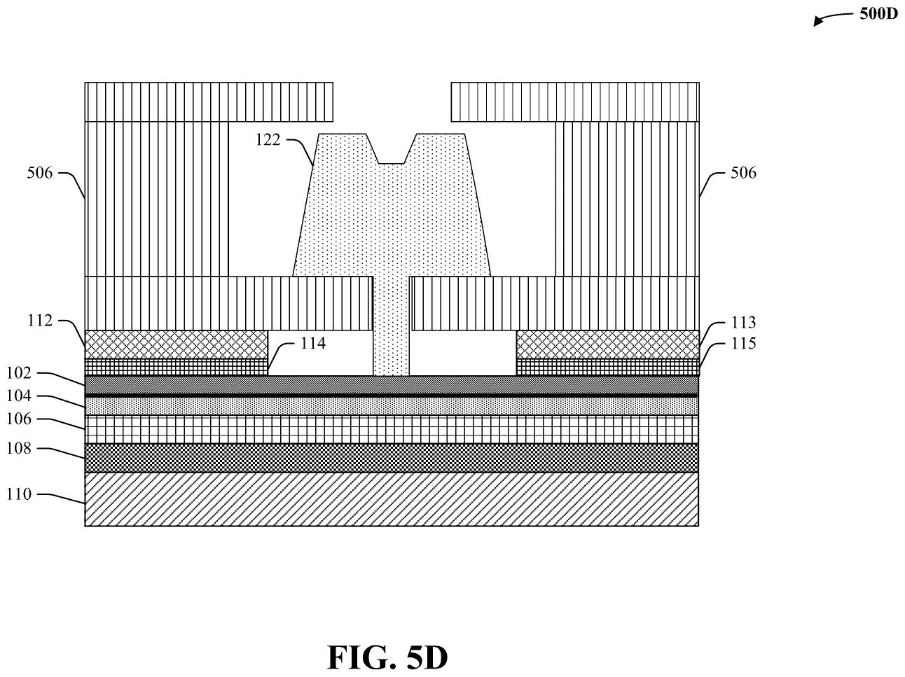

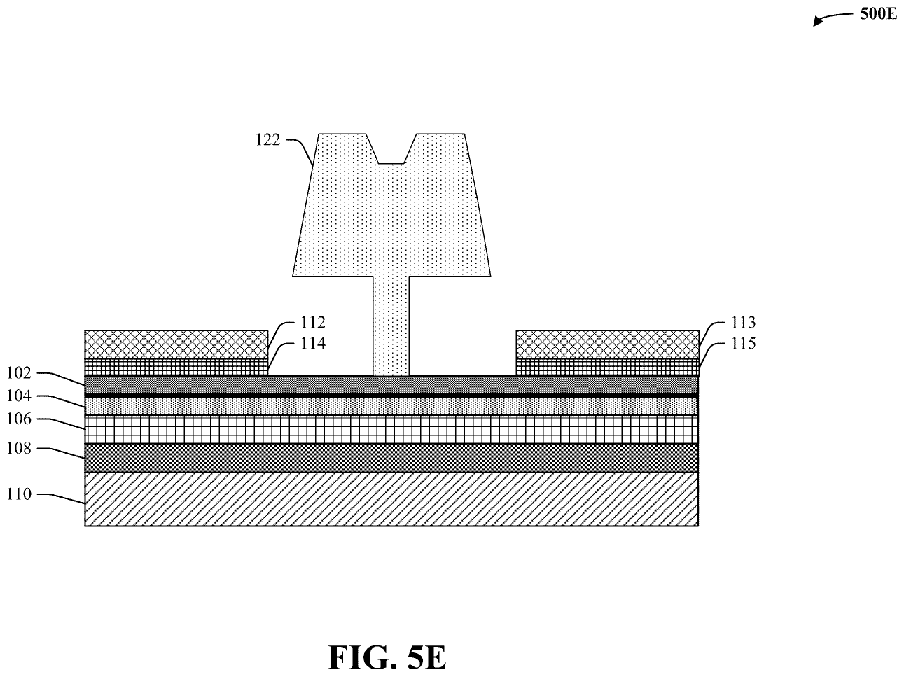

FIGS. 5A-5E illustrates example, non-limiting cross-sectional views of steps in a semiconductor device fabrication process in accordance with one or more embodiments described herein. Repetitive description of like elements and/or processes employed in respective embodiments is omitted for sake of brevity.

FIG. 5A illustrates an example, non-limiting cross-sectional view of a step comprising depositing the plurality of semiconductor layers in accordance with one or more embodiments described herein. Illustrated in FIG. 5 is a heterostructure (e.g., a structure composed of layers of different semiconductor materials) containing the plurality of semiconductor layers, an etch stop 502, and a doped contact layer 504. Deposition can be performed to form the plurality of semiconductor layers, the etch stop 502, and the doped contact layer 504.

In some embodiments, although not shown, the semiconductor device can comprise one or more quantum wells connected to the channel 106 via the doped contact layer 112 and the doped contact layer 113. The one or more quantum wells can be deposited on the channel 106.

Deposition is any process that grows, coats, or otherwise transfers a material onto a substrate. Available technologies include, but are not limited to, dielectric spin-on, thermal oxidation, physical vapor deposition (PVD), chemical vapor deposition (CVD), electrochemical deposition (ECD), molecular beam epitaxy (MBE), or atomic layer deposition (ALD) among others.

FIG. 5B illustrates an example, non-limiting cross-sectional view of a step comprising depositing of a tri-layer resist stack 506 on the doped contact layer 504 in a semiconductor device fabrication process in accordance with one or more embodiments described herein. The tri-layer resist stack 506 is used to define the shape of the T-gate 122. Any other suitable methods to facilitate placement of the T-gate 122 can be employed.

FIG. 5C illustrates an example, non-limiting cross-sectional view of a step comprising etching of the doped contact layer 504 to provide access to the barrier layer 102 in a semiconductor device fabrication process in accordance with one or more embodiments described herein. Etching is any process that selectively removes a doped layer on top of a barrier layer to provide access to the barrier for subsequent device fabrication steps. Etching of the doped contact layer 504 results in doped contact layer 112, doped contact layer 113, etch stop 114 and etch stop 115.

FIG. 5D illustrates an example, non-limiting cross-sectional view of a step comprising creation of T-gate 122 in a semiconductor device fabrication process in accordance with one or more embodiments described herein. After etching, liftoff can be performed to result in formation of the T-gate 122. Liftoff is any process that dissolves a sacrificial layer of material to remove excess deposited material, leaving behind a desired pattern on the substrate.

FIG. 5E illustrates an example, non-limiting cross-sectional view of a step comprising removal of the tri-layer resist stack 506 to leave the T-gate 122 in a semiconductor device fabrication process in accordance with one or more embodiments described herein. Following removal of the tri-layer resist stack 506, a first step of metallization can be performed to form the TS contact layer 118 and the TS contact layer 119. After the first step of metallization, a second step of metallization can be performed to for the source contact 120 on TS contact layer 118 and the drain contact 121 on TS contact layer 119. The resulting semiconductor device after both metallization steps is depicted by FIG. 1.

In some embodiments, patterning can be performed after deposition of one or more layers of the semiconductor device (e.g., source contact 120, drain contact 121, barrier layer 102, channel 106). For example, after the barrier layer 102 is deposited, patterning can be performed to define and create exposed areas on the barrier layer 102 that can be etched to define a source region, a drain region, and a region for T-gate 122.

As discussed in one or more embodiments herein, patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light. The exposed regions are then washed away by a developer solution. After etching or other processing, the remaining photoresist is removed. After transferring the pattern, the patterned photoresist is removed utilizing resist stripping processes, such as wet chemical clean or ashing. Ashing can be used to remove a photoresist material, amorphous carbon, or organic planarization (OPL) layer. Ashing is performed using a suitable reaction gas, for example, O₂, N₂, H₂/N₂, O₃, CF₄, or any combination thereof. Patterning also includes electron-beam lithography, nanoimprint lithography, and reactive ion etching.

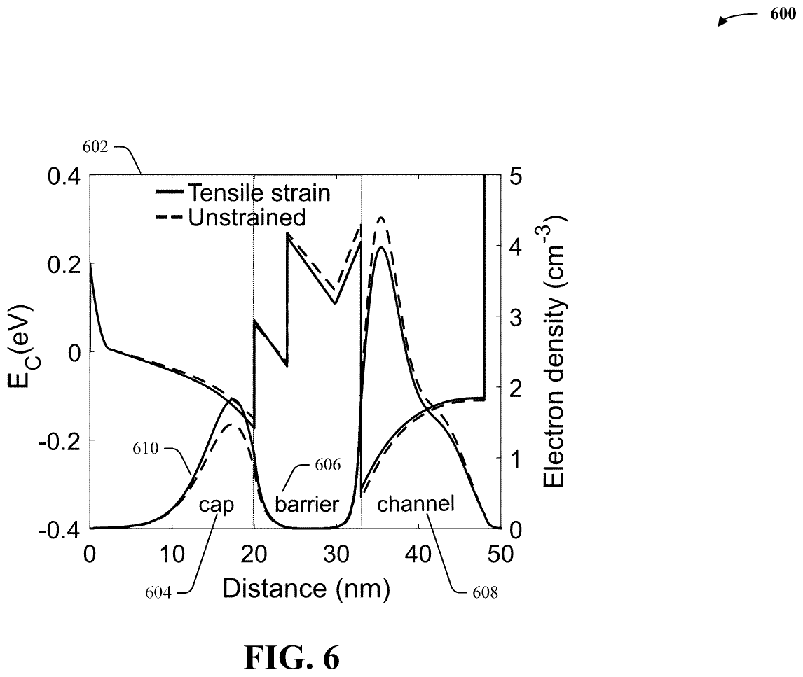

FIGS. 6-11 illustrate experiment results of performance of a fabricated strained ohmic contact semiconductor device.

FIG. 6 illustrates an example, non-limiting graph of electron density in a strained ohmic contact semiconductor device in accordance with one or more embodiments described herein. Repetitive description of like elements and/or processes employed in respective embodiments is omitted for sake of brevity.

Graph 602 depicts, by lines 610, electron density (cm⁻³) of a semiconductor device comprising TS contact layers (e.g., non-dashed line) and a semiconductor device without TS contact layers (e.g., dashed lines) throughout the semiconductor devices. Graph 602 plots electron density against distance (nm) through the semiconductor devices. More specifically, electron density of the semiconductor devices is measured through the doped contact layer 112, the barrier layer 102, and the channel 106 (e.g., shown by 604, 606, and 608 respectively). As shown, the semiconductor device comprising TS contact layers experiences an increase or peak in electron carrier density in the doped contact layer 112, close to the barrier layer 102, indicating an induction of electron carrier density at the barrier layer 102. Such induction of electron carrier density increases tunneling rate (e.g., probability of electrons tunneling though the barrier layer 102), and thus reduces barrier resistance by providing more available electrons to tunnel through the barrier layer 102. Additionally, electron carrier density has an exponential relationship with tunnelling rate, meaning an increase in electron carrier density results in an exponential increase in tunneling rate. Conversely, the semiconductor device without TS contact layers experiences a lower electron carrier density near the barrier layer 102 than the semiconductor device comprising TS contact layers.

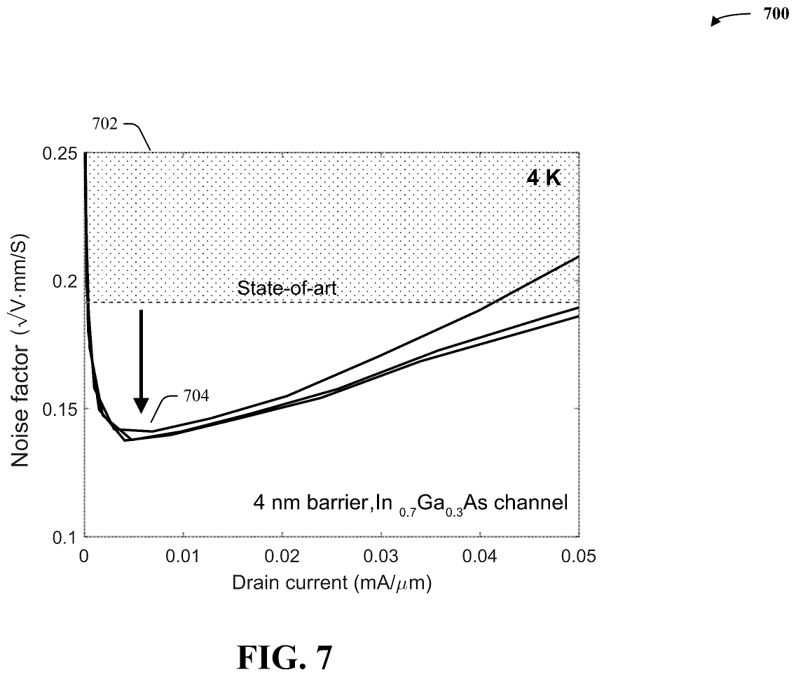

FIG. 7 illustrates an example, non-limiting graph of noise levels in a strained ohmic contact semiconductor device in accordance with one or more embodiments described herein.

Graph 702 depicts noise factor against drain current in a semiconductor device comprising TS contact layers. As shown, the strained ohmic contact semiconductor device, depicted by lines 704) exhibits a significant decrease in noise indication factor

$$( e . g . , \frac{\sqrt{{I}_{DS}}}{{g}_{m}} )$$

than state-of-the-art semiconductor devices at target temperatures of 4 K, thereby indicating that the TS contact layers can reduce noise of a semiconductor device.

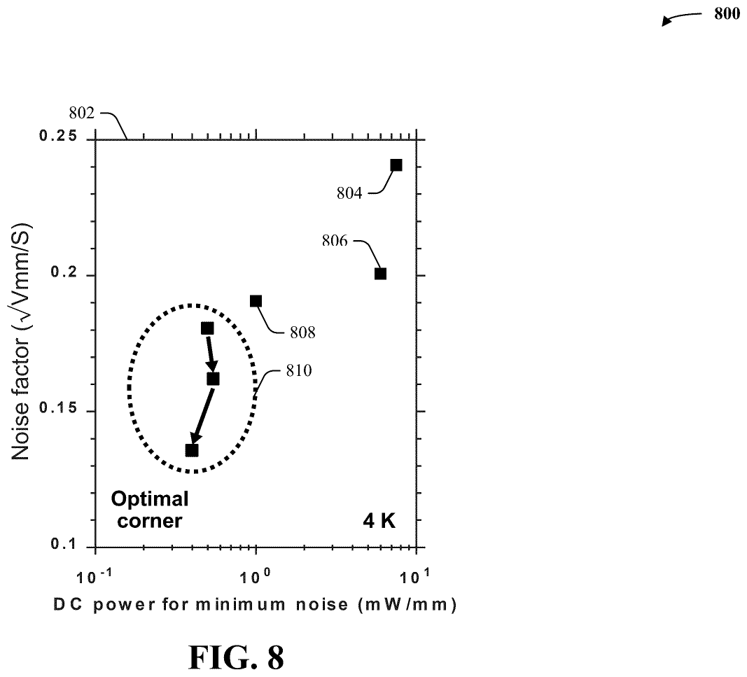

FIG. 8 illustrates an example, non-limiting graph of noise levels in a strained ohmic contact semiconductor device in accordance with one or more embodiments described herein.

Graph 802 depicts three benchmarks 810 achieved by a strained ohmic contact semiconductor device compared to state-of-the-art (e.g., 804, 806, 808). Graph 802 plots noise factor against DC power for minimum noise at target temperature 4 K. As shown, the strained ohmic contact semiconductor device exhibits a significant decrease (e.g., decreases noise factor by approximately 0.055 mm/S than state-of-the-art 808) in noise factor and power than the state-of-the-art.

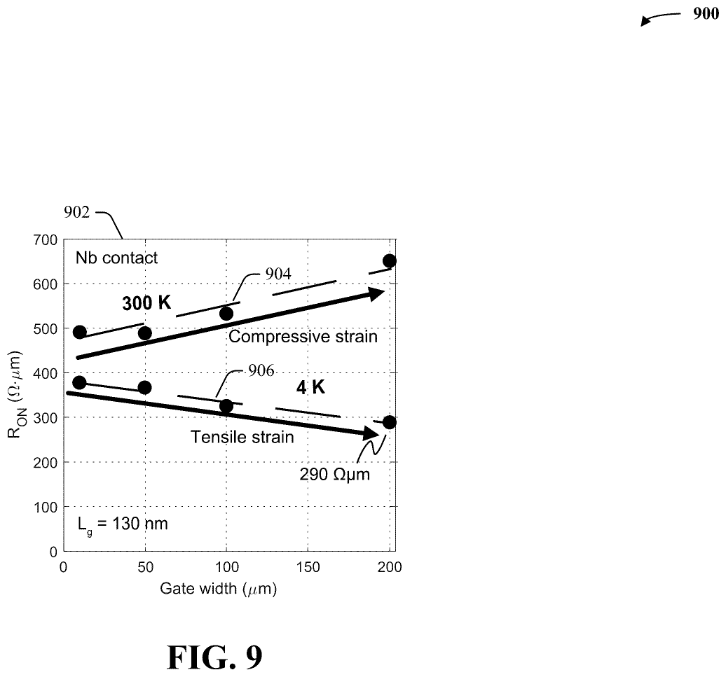

FIG. 9 illustrates an example, non-limiting graph of on-state resistance in a strained ohmic contact semiconductor device in accordance with one or more embodiments described herein.

Graph 902 plots on-state resistance (e.g., R_{ON}, measure of resistance encountered by current flow when semiconductor device is in its conducting state) against gate width at 300 K, depicted by line 904, and at target temperature 4 K, depicted by 906. As shown, tensile strain at the target temperature 4 K increases as semiconductor device increases, and thereby reducing on-state resistance.

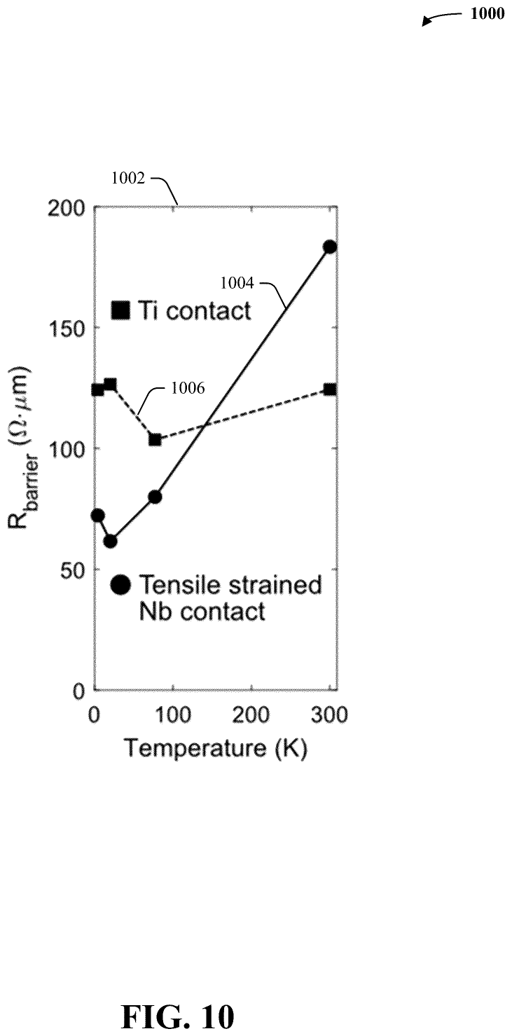

FIG. 10 illustrates an example, non-limiting graph of barrier resistance in a strained ohmic contact semiconductor device in accordance with one or more embodiments described herein.

Graph 1002 plots barrier resistance against temperature for a semiconductor device comprising a tensile strained Nb contact layer (e.g., TS contact layer 118, TS contact layer 119), as depicted by line 1004, and a semiconductor device comprising a Titanium (Ti) contact layer, as depicted by line 1006. As shown, the semiconductor device comprising a tensile strained Nb contact layer exhibits a significant decrease in barrier resistance at low temperatures, particularly around target temperature 4 K, than the semiconductor device comprising the Ti contact layer.

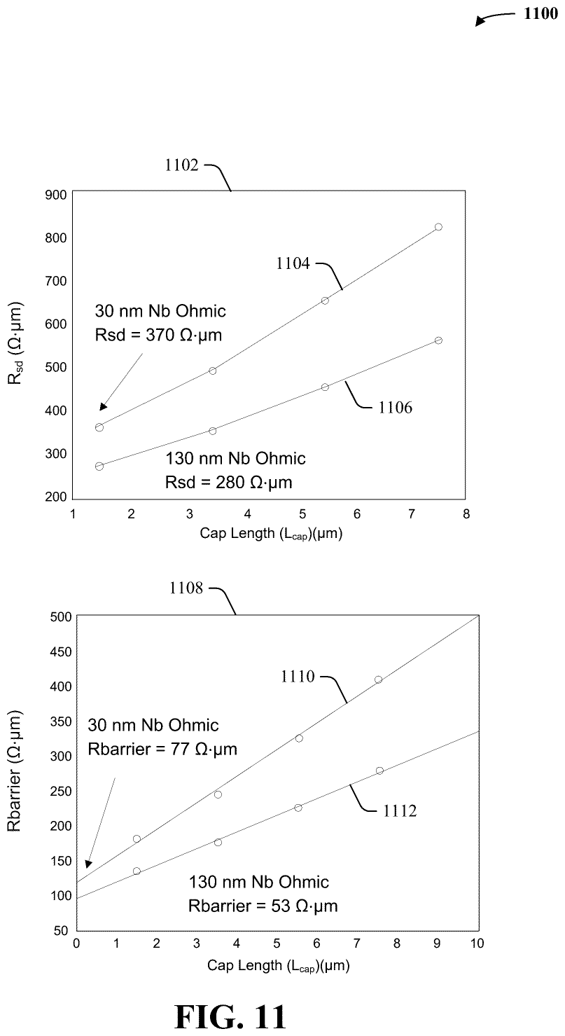

FIG. 11 illustrates an example, non-limiting graph of barrier resistance and source-drain resistance in a strained ohmic contact semiconductor device in accordance with one or more embodiments described herein.

Graph 1102 plots source-drain resistance (e.g., R_{sd}, resistance encountered by current flowing between the source region and drain region) against cap length (e.g., L_{cap} 302) of a semiconductor device comprising a 30 nm Nb ohmic contact layer, depicted by line 1104, and a semiconductor device comprising a 130 nm Nb ohmic contact layer, depicted by line 1106, to illustrate affects of thickness of the TS contact layers on source-drain resistance. As shown, the 130 nm Nb ohmic contact layer exhibits decreased source-drain resistance than the 30 nm Nb ohmic contact layer. Graph 1108 plots barrier resistance against cap length for the semiconductor devices described with respect to graph 1102. As shown, the 130 nm Nb ohmic contact layer, depicted by line 1110, exhibits decreased barrier resistance than the 30 nm Nb ohmic contact layer, depicted by line 1112. In accordance with embodiments described herein, the thickness of the TS contact layer 118 and TS contact layer 119 can be set during metallization to control the amount of strain provided to reduce parasitic resistances in the semiconductor device.

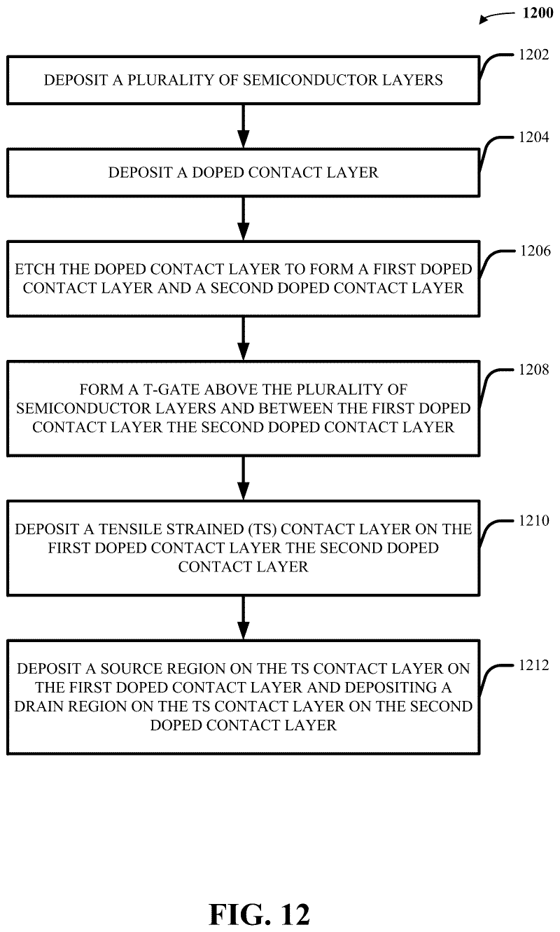

FIG. 12 illustrates a flow diagram of an example, non-limiting method 1200 in accordance with one or more embodiments described herein. Repetitive description of like elements and/or processes employed in respective embodiments is omitted for sake of brevity.

At 1202, the non-limiting method 1200 can comprise depositing a plurality of semiconductor layers (e.g., 102, 104, 106, 108, 110).

At 1204, the non-limiting method 1200 can comprise depositing a doped contact layer (e.g., 504).

At 1206, the non-limiting method 1200 can comprise etching the doped contact layer to form a first doped contact layer (e.g., 112) and a second doped contact layer (e.g., 113).

At 1208, the non-limiting method 1200 can comprise forming a T-gate (e.g., 122) above the plurality of semiconductor layers and between the first doped contact layer the second doped contact layer.

At 1210, the non-limiting method 1200 can comprise depositing a TS contact layer on the first doped contact layer the second doped contact layer (e.g., 118, 119).

At 1212, the non-limiting method 1200 can comprise depositing a source region (e.g., 120, 121) on the TS contact layer on the first doped contact layer and depositing a drain region on the TS contact layer on the second doped contact layer.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

It is, of course, not possible to describe every conceivable combination of methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a plurality of semiconductor layers that comprises a barrier layer on top of a quantum well layer;
a T-gate above the plurality of semiconductor layers and between a first contact layer and a second contact layer; and
a tensile strained (TS) contact layer on the first and the second contact layer, wherein the TS contact layer is a stiff metal deposited with tensile internal stress to induce a reduction of tunneling resistance through the barrier layer.

2. The semiconductor device of claim 1, wherein the TS contact layer comprises a thickness between 60 nm to 200 nm.

3. The semiconductor device of claim 2, wherein thickness of the TS contact layer is set to adjust strain on the first and the second contact layer.

4. The semiconductor device of claim 1, wherein the TS contact layer comprises sputtered niobium (Nb), tungsten (W), or molybdenum (Mo) deposited under conditions of tensile stress above 100 MPa.

5. The semiconductor device of claim 1, wherein strain on the first and the second contact layer via the TS contact layer compressively stresses the plurality of semiconductor layers by at least 100 MPa when cooled to temperatures below 77 K.

6. The semiconductor device of claim 1, wherein the TS contact layer comprises a plurality of stiff metal layers with a combined internal tensile stress of above 100 MPa, and wherein the plurality of stiff metal layers comprises a Young's modulus above 100 GPa.

7. The semiconductor device of claim 1, further comprising:
a source region on the TS contact layer on the first contact layer; and
a drain region on the TS contact layer on the second contact layer.

8. The semiconductor device of claim 1, wherein the plurality of semiconductor layers further comprises:
a substrate located at a bottom of the plurality of semiconductor layers; and
a buffer layer above the substrate to connect the substrate to other layers of the plurality of semiconductor layers.

9. The semiconductor device of claim 1, wherein a linear expansion coefficient as a function of temperature of the stiff metal is larger than the linear expansion coefficient as a function of temperature of the plurality of semiconductor layers.

10. A method, comprising steps of:
forming a plurality of semiconductor layers that comprises a barrier layer on top of a quantum well layer;
placing a T-gate above the plurality of semiconductor layers and between a first contact layer and a second contact layer; and
depositing a tensile strained (TS) contact layer on the first and the second contact layer, wherein the TS contact layer is a stiff metal deposited with tensile internal stress to induce a reduction of tunneling resistance through the barrier layer.

11. The method of claim 10, wherein the TS contact layer comprises a thickness between 60 nm to 200 nm.

12. The method of claim 11, wherein thickness of the TS contact layer is set to adjust strain on the first and the second contact layer.

13. The method of claim 10, wherein the TS contact layer comprises sputtered niobium (Nb), tungsten (W), or molybdenum (Mo) deposited under conditions of tensile stress above 100 MPa.

14. The method of claim 10, wherein strain on the first and the second contact layer via the TS contact layer compressively stresses the plurality of semiconductor layers by at least 100 MPa when cooled to temperatures below 77 K.

15. The method of claim 10, wherein the TS contact layer comprises a plurality of stiff metal layers with a combined internal tensile stress above 100 MPa, and wherein the plurality of stiff metal layers comprises a Young's modulus above 100 GPa.

16. The method of claim 10, further comprising:
depositing a source region on the TS contact layer on the first contact layer; and
depositing a drain region on the TS contact layer on the second contact layer.

17. The method of claim 10, wherein a linear expansion coefficient as a function of temperature of the stiff metal is larger than the linear expansion coefficient as a function of temperature of the plurality of semiconductor layers.

18. A semiconductor device, comprising:
a plurality of semiconductor layers that comprises an indium aluminum arsenide (InAlAs) barrier layer on top of an InGaAs quantum well;
a T-gate above the plurality of semiconductor layers and between a first indium gallium arsenide (InGaAs) contact layer and a second InGaAs contact layer; and
a tensile strained (TS) contact layer on the first and the second InGaAs contact layer, wherein the TS contact layer is a stiff metal deposited with tensile internal stress to induce a reduction of tunneling resistance through the InAlAs barrier layer.

19. The semiconductor device of claim 18, wherein a linear expansion coefficient as a function of temperature of the stiff metal is larger than the linear expansion coefficient as a function of temperature of the plurality of semiconductor layers.

20. The semiconductor device of claim 18. wherein the TS contact layer comprises sputtered niobium (Nb), tungsten (W), or molybdenum (Mo) deposited under conditions of tensile stress above 100 MPa.
